(19) United States
(12) Patent Application Publication
(10) Pub. No.: US 2007/0210257 A1
(43) Pub. Date: Sep. 13, 2007

(54) Radiation image pickup apparatus

(75) Inventors: Satoshi Masuda, Osaka (JP); Naoki Masazumi, Kobe-shi (JP)

Correspondence Address: BRINKS HOFER GILSON & LIONE, P.O. BOX 10395, CHICAGO, IL, 60610, US

(73) Assignee: KONICA MINOLTA MEDICAL AND GRAPHIC, INC.

(21) Appl. No.: 11/528,814

(22) Filed: Sep. 26, 2006

(30) Foreign Application Priority Data
Sep. 29, 2005 (JP) JP2005-284407

(51) Int. Cl. G01T 1/24; H01L 27/146; H01L 25/00; H01L 27/00

(52) U.S. Cl. 250/370.09

(57) ABSTRACT

At the time of the radiation irradiation, in the photo diode of all detecting elements G11-G1n, the photoelectric conversion operation is conducted. In this case, when TFT of the detecting elements used for conducting the radiation measurement is made ON, it is connected to each output circuit of the output circuit group 13, and by the detecting element used for conducting the radiation measurement, the photoelectric conversion operation is conducted and obtained electric signal is held in the output circuit. This electric signal held in the output circuit is outputted for each predetermined interval, and it is confirmed whether the radiation amount is more than a predetermined index value.

This application is based on Japanese Patent Application No. 2005-284407 filed on Sep. 29, 2005, in Japanese Patent Office, the entire content of which is hereby incorporated by reference.

### BACKGROUND OF THE INVENTION

The present invention relates to a radiation image pickup apparatus for detecting the radiation used for a medical diagnostic machine, non-destructive inspection machine as an electric signal, particularly, to a radiation image pickup apparatus by the passive system by which an incident radiation is converted into the electric signal and which directly outputs without amplifying the output of the conversion element which generates the electric signal corresponding to the radiation amount.

Recently, in an area in which the image obtained by the radiation by the medical image diagnosis or non-destructive inspection is used, following the film less-making and the network-making, the digitizing of the obtained image is quickly accelerated, and as one of these realizing methods, the photographing method using a Flat Panel Detector (Flat Panel Detector: FDP) which can process the radiation which transmitted the subject is directly detected, as the digital information, is proposed. Because in this FPD, X-ray which is the light source is not converged by the lens, it is necessary that the subject is read at the life-size, and FPD is composed of large area. In FIG. 17, an example of the radiation photographing system using FPD is shown.

As shown in FIG. 17, in a photographing room 901 for photographing the subject 900, a radiation image pickup apparatus provided with an X-ray tube 904 for irradiating X-ray and FPD 903 for converting the received X-ray into the electric signal, is provided. Further, in another room 902, a computer 905 for inspecting, storing, processing the obtained image is installed. Then, when X-ray is irradiated from the X-ray tube 904, FPD 903 detects the X-ray transmitted the subject 900, and converts the detected X-ray signal into the electric signal. This electric signal is sent to the computer 905 by the wire-less or the wire, and the user waiting in another room 902 can instantly confirm the photographing data.

Further, from a printer 906 connected to this computer 905, the image pickup data can be outputted, and in the case where the facility is a medical facility into which PACS (Picture Archiving and Communication System) system 907 is introduced, when the image pickup data is up-load to a server of this PACS, X-ray image pickup data of the subject 900 can be inspected from a remote position. Hereupon, PACS is a communication system of storing, transmission, search of the medical image recently introduced, recently, not limited in the facility, a system having a structure which can transmit, search the medical image between facilities, exists also.

Hereupon, the above FPD has a structure shown in a general block diagram of FIG. 18. The FPD 903 shown in FIG. 18 has many switching elements and charge accumulation elements matrix-likely, on a glass substrate 913 whose size is sensor image receiving surface, and these elements are collected and compose a panel 912. Then, by a pair of switching element 915 and electric charge accumulation element 916 of them, an detecting element 914 is structured. Hereupon, as this switching element, the thin film transistor (Thin Film Transistor: TFT) composed of amorphous silicon (a-Si) is used.

Further, on the upper surface of a panel 912, X-ray conversion layer 911 for converting the X-ray into the electric signal is provided. The electric signal converted by this X-ray conversion layer 911 is accumulated in the electric charge accumulation element 916. When the switching element 915 of the detecting element specified by the gate line 917 arranged vertically and horizontally is controlled to ON-state, the electric signal outputted through this switching element 915 is read-out through the charge transfer line 918. Hereupon, 2 kinds of a direct conversion system and an indirect conversion system whose processes in which detected X-ray is converted into the electric signal by a component constituting the X-ray conversion layer 911 in FIG. 18, are different, exist.

In the direct conversion system, as FIG. 19(a), as the X-ray conversion layer 911, amorphous selenium (a-Se) 921 is used. This amorphous selenium 921 has a characteristic which generates a predetermined amount of electron and positive hole corresponding to the strength of detected X-ray, hereby, X-ray is directly converted into the electric signal. Further, to this amorphous selenium 921, the DC bias voltage of about 3000 V is impressed, and according to the polarity of this impressed bias, the electric signal is moved to the detecting element electrode, and accumulated in the electric charge accumulation element 916. Then, when the switching is controlled by the switching element 915, this accumulated electric signal is read-out in the later stage circuit.

On the one hand, the indirect conversion system, as FIG. 19(b), as the X-ray conversion layer 911, phosphorous body 925 and photoelectric conversion element 926 are used. To this photoelectric conversion element 926, DC bias of about 5-10 V is impressed. Further, the phosphorous body 925 has a characteristic which generates a predetermined amount of light corresponding to the strength of detected X-ray, when the photoelectric conversion element 926 receives this generated light, a predetermined amount of electric signal is generated corresponding to the received light amount, and this generated electric signal is accumulated in the electric charge accumulation element 916, and it is structured such that when the switching is controlled by the switching element 915, this accumulated electric signal is read-out in the later stage circuit. In this case, when photo diode is used as the photoelectric conversion element 926, generally, the photodiode combines with the electric charge accumulation element 916. Hereupon, a phenomenon that the incident X-ray is converted into the visual light, is called scintillation, and the phosphorous body 925 provided for generating this scintillation is also called scintillator.

The radiation image pickup apparatus provided with such structured FPD, it is necessary that the exposed amount of X-ray to the subject 900 is suppressed to minimum limit, and in order to obtain the high quality image, X-ray irradiation is conducted so that the charge accumulation amount in the electric charge accumulation element 916 is fully obtained. Therefore, when the transmission X-ray amount at the time of X-ray irradiation is measured, and the cumulative X-ray irradiation amount necessary for forming the good quality image is confirmed, the X-ray photo timer function for stopping the X-ray irradiation is provided (refer to Patent No. 3548507). In this radiation image pickup apparatus of Patent Document 1, when the non-destructive read-out operation by which the output is conducted under the condition while the electric charge accumulated in the photoelectric conversion element is accumulated, is conducted, the electric charge can be held also after the signal output. Therefore, the transmission X-ray amount is confirmed based on the signal obtained by this accumulated electric charge, and the X-ray irradiation can be stopped.

However, in the structure of Patent Document 1, in order to conduct the non-destructive read-out operation, as a source follower circuit, it is an active system in which the element or circuit for conducting the amplitude operation is provided at the output section of each detecting element. Therefore, when there is dispersion per each of detecting elements in the characteristic of element arranged in order to conduct this amplitude operation, the dispersion is generated also in the output characteristic of each detecting element, and it appears as the fixed pattern noise (FPN). This FPN has a tendency that it becomes large as the image pickup area becomes large, and is not adequate to the radiation image pickup apparatus in which the large area image pickup is necessary. Further, there is a problem that the threshold voltage is sifted in TFT, and because the analogous characteristic is unstable, it is very difficult that the active system sensor in which the light having the broad image pickup area is the prime number, is realized by using TFT.

### SUMMARY OF THE INVENTION

In view of such a problem, the object of the present invention is to provide a passive system radiation image pickup apparatus by which the photo timer function is realized by a part of detecting elements for conducting the image pickup operation, and its detecting element output can also be used as the image data.

In order to attain the above object, the radiation image pickup apparatus of the present invention is characterized in that: it is provided with a plurality of detecting elements arranged in a matrix arrangement in which each of the plurality of detecting elements has a converting element to convert radiation incident from a radiation source into an electric charge corresponding to the amount of the radiation and a switch connected to the converting element; a plurality of charge transfer lines, each of the plurality of charge transfer lines provided in correspondence to one column of the matrix arrangement and connected to switches of detecting elements on the one column; an output circuit to retain electric charges from the plurality of charge transfer lines and to output electric signals corresponding to the electric charges; and a control section to select a first detecting element to measure an amount of radiation during a irradiation period from the plurality of detecting elements, wherein during the irradiation period, the control section controls all the converting elements of the plurality of detecting elements including the first detecting element converts radiation into electric charges respectively, and the control section makes the switch of the first detecting element “ON” so as to transfer the electric charge trough a corresponding charge transfer line to the output circuit so that the output circuit accumulates electric charge coveted by the converting element of the first detecting element and the control section reads periodically an electric signal corresponding to the electric charge accumulated in accordance with the irradiation period.

In such a radiation image pickup apparatus, the first detecting element may also be plural ones. In this case, based on a value in which the signal values of the electric signals from the plural first detecting elements are addition averaged, the measurement of the radiation amount may also be conducted, or based on the maximum value of the signal values of the electric signals from the plural first detecting elements, the measurement of the radiation amount may also be conducted.

From all of the detecting elements including the first detecting element, the images data based on the incident radiation may also be outputted. Then, the output circuits are connected to respective of the charge transfer lines and has the signal holding section for holding the electric signal from the detecting element and the reset section for resetting the signal holding section, and before the radiation irradiation, the reset of the signal holding section by the reset section and the reset of the conversion element by making the switches of all the detecting elements ON are conducted.

Further, the first detecting element may also be a plurality of detecting elements arranged over a plurality of lines. In this case, the output circuit may also be composed of a plurality of output circuits provided on each of lines.

In the above radiation image pickup apparatus, the first detecting element may also be set for each time of photographing. In this case, when a faint radiation or visible light is irradiated before photographing, the photographing range on the subject is confirmed, and the first detecting element may also be set.

In the above radiation image pickup apparatus, when a faint radiation or visible light is irradiated before photographing, the photographing range on the subject is confirmed, and the irradiation range of the radiation may also be set.

In the above radiation image pickup apparatus, the output circuit has the operation amplifier in which the reversal input terminal is connected to the charge transfer line, and the reference voltage is given to the non-reversal input terminal, and the capacitance element connected between the reversal input terminal and the output terminal of the operation amplifier.

Further, the above object can be attained by the following radiation image pickup method.

A radiation image pickup method with a radiation image pickup apparatus equipped with a sensor including a plurality of detecting elements arranged in a matrix arrangement in which each of the plurality of detecting elements has a converting element to convert radiation incident thereon into an electric charge corresponding to the amount of the radiation and a switch connected to the converting element; a plurality of charge transfer lines, each of the plurality of charge transfer lines provided in correspondence to one column of the matrix arrangement and connected to switches of detecting elements on the one column; an output circuit to retain electric charges from the plurality of charge transfer lines and to output electric signals corresponding to the electric charges; and a control section to control the sensor, the plurality of charge transfer lines and the output circuit; the radiation image pickup method comprises the steps of:

selecting a first detecting element to measure an amount of radiation during a irradiation period from the plurality of detecting elements;

controlling all the converting elements of the plurality of detecting elements including the first detecting element to convert radiation into electric charges respectively and the switch of the first detecting element to become “ON” so as to transfer the electric charge trough a corresponding charge transfer line to the output circuit during the irradiation period so that the output circuit accumulates electric charge coveted by the converting element of the first detecting element; and

reading periodically an electric signal corresponding to the electric charge accumulated in accordance with the irradiation period.

According to the present invention, the first detecting element for measuring the radiation amount is selected from the detecting element for conducting the radiation image pickup, and when the electric signal obtained by conducting the converting operation by the first detecting element, is held in the output circuit, it can be structured such that it is not necessary that the electric signal from the detecting element is amplified. Therefore, the element conducting the amplifying operation or circuit like as the source follower circuit is not necessary, and the generation of the fixed pattern noise can be prevented. Further, the photo timer function can be realized without separately providing a special output circuit, and the apparatus structure can be simplified. Further, because the output of the first detecting element can also be used as the image data, the deterioration of the resolution is not caused.

### BRIEF DESCRIPTION OF THE DRAWINGS

FIG. 1 is a block diagram showing the internal structure of a radiation image pickup apparatus in each embodiment of the present invention.

FIG. 2 is an outline block diagram showing the internal structure of FPD in the radiation image pickup apparatus of the first embodiment.

FIG. 3 is a circuit view showing the detecting element in FPD in FIG. 2 or the structure of an output circuit.

FIG. 4 is a layout view when one detecting element is viewed from the upper surface.

FIG. 5 is a sectional view cut on A-B of the detecting element of FIG. 5.

FIG. 6 is a timing chart showing the relationship between each signal in the first example of the image pickup operation of FPD of FIG. 2 and the outputted image data.

FIG. 7 is a view showing the relationship between the detecting element aligning line for the X-ray amount measurement in FPD conducting the operation in the operation example of FIG. 6, and the order for each line for outputting the image data.

FIG. 8 is a timing chart showing the relationship between each signal in the second example of the image pickup operation of FPD of FIG. 2, and the outputted image data.

FIG. 9 is a view showing the relationship between the detecting element aligning line for the X-ray amount measurement in FPD for conducting the operation of the operation example of FIG. 8, and the order for each line for outputting the image data.

FIG. 10 is a timing chart showing the relationship between each signal in the third example of the image pickup operation of FPD of FIG. 2, and the outputted image data.

FIG. 11 is a view showing the relationship between the detecting element aligning line for the X-ray amount measurement in FPD for conducting the operation of the operation example of FIG. 10, and the order for each line for outputting the image data.

FIG. 12 is a view showing the condition when the visible light is irradiated, and the position and the size of the subject are confirmed.

FIG. 13 is an outline block diagram showing the internal structure of FPD in the radiation image pickup apparatus of the second embodiment.

FIG. 14 is a view showing the relationship between the detecting element aligning line for the X-ray amount measurement in FPD of FIG. 13, and the order for each line for outputting the image data.

FIG. 15 is a view showing the relationship between the detecting element aligning line for the X-ray amount measurement in FPD of the third embodiment, and the order for each line for outputting the image data.

FIG. 16 is a timing chart showing the relationship between each signal in the image pickup operation of FPD of the third embodiment, and the outputted image data.

FIG. 17 is a conceptual view of the X-ray photographing system by FPD.

FIG. 18 is a conceptual block diagram showing the structure of FPD.

FIG. 19 is a block diagram for comparing the direct conversion system to the indirect conversion system.

### DETAILED DESCRIPTION OF THE PREFERRED EMBODIMENT

Hereinafter, an embodiment of the present invention will be explained with reference to the drawings, however the present invention is not limited to this embodiment.

(The Structure of the Radiation Image Pickup Apparatus)

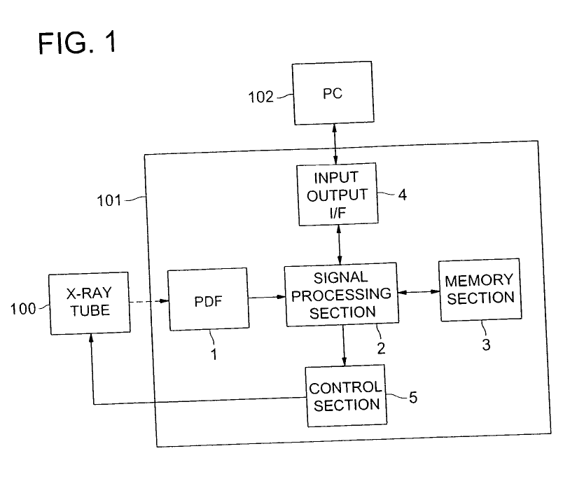

Initially, referring to the drawings, the structure of the radiation image pickup apparatus which is a common in each embodiment of the present invention, will be described. FIG. 1 is a block diagram showing the internal structure of structure of the radiation image pickup apparatus.

The radiation image pickup apparatus 101 shown in FIG. 1 is provided with: FPD1 on which X-ray irradiated from X-ray tube 100 which is the outer radiation source is incident; a signal processing section 2 for processing the image data based on the X-ray incident on FPD1; a memory section 3 for storing the image data processed in the signal processing section 2; an input output interface (I/F) 4 to which the image data held in the memory section 3 is given, and from which it is outputted to the outside computer 102; and a control section 5 to which the image data processed in the signal processing section 2 is given, and by which the operation of the radiation image pickup apparatus 101 is controlled, and the operation control of the FPD1, signal processing section 2 and input output I/F 4 is conducted.

According to the radiation image pickup apparatus 101 of such a structure, when X-ray is irradiated from the X-ray tube 100, in FPD, the incident X-ray is converted into an electric charge, and this electric charge is retained until it is outputted to a signal processing section after a radiography was completed.

In this radiation image pickup apparatus 101, the detecting element of one part of FPD1 is used as the sensor for the X-ray amount detection. On a condition that an electric charge generated by the detecting element for the X-ray amount detection is retained in an inner part of FPD (in detail, an output circuit), the value of an electric signal corresponding to the retained electric charge is outputted periodically to an signal processing section 2. In the signal processing section 2, X-ray amount irradiated based on the image data outputted from this detecting element, is confirmed. Then, when the signal expressing the irradiated X-ray amount is given to the control section 5, it is confirmed whether the X-ray amount irradiated by this signal is more than a predetermined index value, and when confirmed that it is more than index value, it is indicated to the X-ray tube 100 that the irradiation of X-ray is stopped. After that, when the electric signals obtained in all detecting elements of FPD1 are outputted as image data and given to the signal processing section 2, the calculation processing is conducted by using the memory section 3. This calculation processed image data is stored in the memory section 3, and outputted to the computer 102 by the input output I/F 4.

The radiation image pickup apparatus in following each embodiment, is provided with the structure of FIG. 1 as a common structure. Therefore, in the following each embodiment, the structure and operation of FPD of the radiation image pickup apparatus will be described.

### The First Embodiment

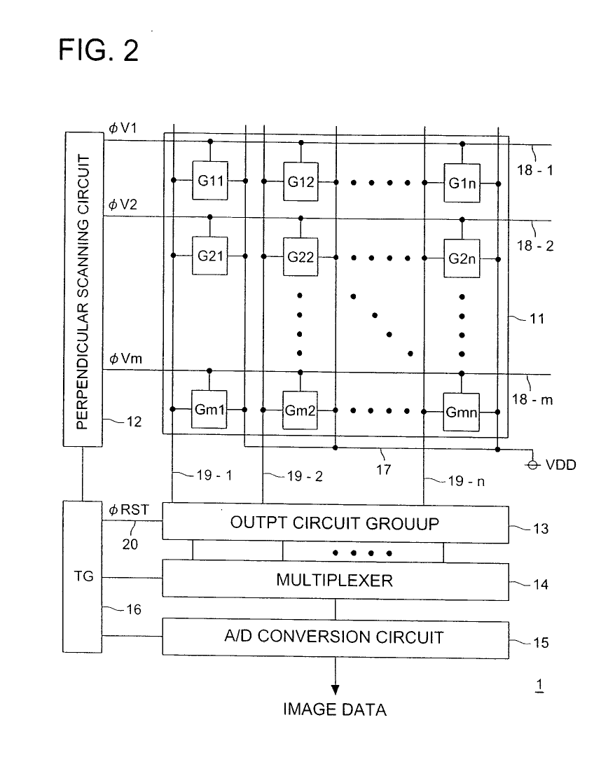

Referring to the drawings, the first embodiment of the present invention will be described. FIG. 2 is an outline block diagram showing the internal structure of FPD in the radiation image pickup apparatus of the present embodiment.

FPD1 is, as shown in FIG. 2, provide with: a sensor section 11 having the detecting elements G11-Gmn provided with the photo diode PD and the thin film transistor T arranged in a form of a matrix; a perpendicular scan circuit 12 for scanning in the perpendicular direction each of detecting elements G11-Gmn of the sensor section 11 at the time of the data output; output circuit group 13 for holding for each line in the matrix arrangement the electric signal outputted from each of detecting elements G11-Gmn of the sensor section 11; a multiplexer 14 for converting the electric signals held in the output circuit group 13 into the serial electric signal for each row; the A/D conversion circuit 15 for converting the electric signal given from the multiplexer 14 into the image data which is the digital data; and the timing generator 16 for specifying respective operation timing of the perpendicular scanning circuit 12, output circuit group 13, multiplexer 14, and A/D conversion circuit 15.

This FPD1 is provided with: the bias line 17 for impressing the DC voltage VDD on each of detecting elements G11-Gmn; line selection lines 18-1-18-m provided for each line for giving the signals ΦV1-ΦVm given for each line from the perpendicular scanning circuit 12 to detecting elements of each line in the sensor section 11; charge transfer line 19-1-19-n provided for each row for outputting the electric signal from the detecting element in the sensor section 11 to the output circuit group 13; and the reset line 20 for giving the reset signal ΦRST for resetting the output circuit group 13 of the sensor section 11 from the timing generator 16 to the output circuit group 13. Hereupon, the signal line for sending and receiving is connected also among the timing generator 16, perpendicular scanning circuit 12, multiplexer 14 and A/D conversion circuit 15, or also between the multiplexer 14 and A/D conversion circuit 15, however, its detailed description will be neglected.

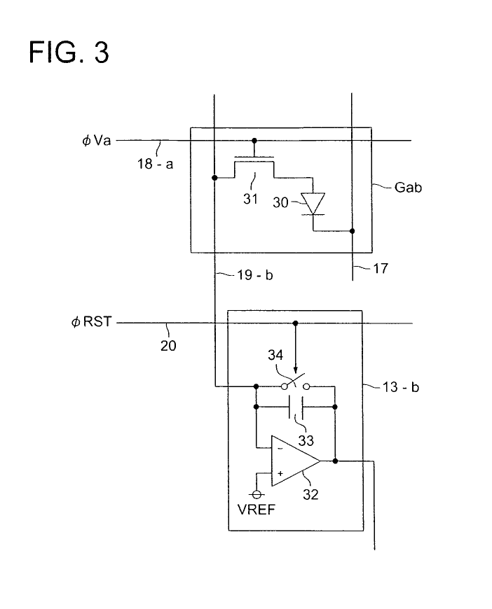

Further, in the output circuit group 13, the output circuit 13-1-13-n connected to the charge transfer line of each row 19-1-19-n are provided. The structure of this output circuit 13-1-13-n and the detecting element G11-Gmn, will be detailed referring to the drawings. Hereupon, in the following, the detecting element Gab of a line and b row is made as the representative, and its structure will be described. That is, in FIG. 3, the circuit structure of the detecting element Gab and the output circuit 13-b will be shown.

The detecting element Gab is provided with, as shown in FIG. 3, the photo diode 30 which is connected to the bias line 17 and in which the DC voltage VDD is impressed on the cathode, TFT 31 in which to the anode of the photodiode PD, the drain electrode is connected, and the source electrode is connected to the charge transfer line 19-b. Then, to the gate electrode of TFT 31, a line selection line 18-a is connected, and the signal ΦVa from the perpendicular scanning circuit 12 is given. The photo diode 30 corresponds to a converting element and TFT 31 corresponds to a switch in the present invention.

The output circuit 13-b provides with so-called charge sensing amplifier structured by the operation amplifier and the capacitor. In details, it provides with the operation amplifier 32 in which the reversal input terminal is connected to the charge transfer line 19-b, and the reference voltage V REF is impressed on the non-reversal input terminal, and the capacitor 33 and a reset section 34 connected in parallel between the reversal input terminal and output terminal. Then, the output terminal of the operation amplifier 32 is connected to the input side of the multiplexer 14, and ON/OFF of the reset section 34 is controlled by the signal ΦRST given through the reset line 20 from the timing generator 16. Such structured charge sensing amplifier is, when the electric charge is held in the capacitor 33, the read-out circuit having an integral function, and as long as the capacitor 33 is not reset, even when the electric signal corresponding to the electric charge is read-out, has the characteristic that the electric charge is held.

In the case where the detecting elements G11-Gmn and the output circuits 13-1-13-n are structured in this manner, when the reset operation of the detecting elements G11-Gmn and the output circuits 13-1-13-n is conducted, the signal ΦRST which becomes high, is given from the timing generator 16, and simultaneously when respective switches 34 of the output circuits 13-1-13-n, are made ON, the signals ΦV1-ΦVm are given from the perpendicular scanning circuit 12, and respective TFTs 31 of the detecting elements G11-Gmn are made ON.

In this case, because the reset section 34 becomes ON, the output terminal of the operation amplifier 32 and the reversal input terminal are connected, and the electric charge accumulated in the capacitor is discharged. Further, because TFT 31 becomes ON, the anode of the photo diode 30 is electrically connected to the output terminal of the operation amplifier 34 through TFT 31 and the reset section 34, and the electric charge accumulated in the anode of the photo diode 30 is discharged. Accordingly, the anode and the capacitor 33 of the photo diode 30 are reset.

Then, when X-ray is irradiated and the image pickup operation is conducted, the signal ΦRST is made low, and the reset section 34 is made OFF. In this case, when the detecting element Gab is made a detecting element for outputting the electric signal for measuring X-ray amount, the signal ΦVa is made high, and TFT 31 is made ON. Hereby, because the photo electric charge obtained when the photo diode 30 is photoelectric converted flows from the anode of the photo diode 30 to the capacitor 33, it is accumulated in the capacitor 33. In this case, because the voltage of the reversal input terminal of the operation amplifier 32 is about equal value to the voltage VREF impressed on the non-reversal input terminal of the operation amplifier 32 and becomes constant, based on the electric charge accumulated in the capacitor 33, the voltage value of the output terminal of the operation amplifier 32 is changed. This voltage value of the output terminal of the operation amplifier 32 is given to the multiplexer 14.

On the one hand, when not a detecting element for X-ray amount measurement, it is a detecting element for conducting normal image pickup operation, the signal ΦVa is made low, and TFT 31 is made OFF. Hereby, the photo diode 30 is photo electric converted, and obtained light electric charge is accumulated in anode of the photo diode 30. Then, at the time of the signal read-out of the detecting element Gab, when the signal ΦVa is made high, and TFT is made ON, the electric charge accumulated in the anode of the photo diode 30, is accumulated in the capacitor 33, and the voltage value of the output terminal of the operation amplifier 32 is changed, and the voltage value of the output terminal of this operation amplifier 32 is given to the multiplxer 14.

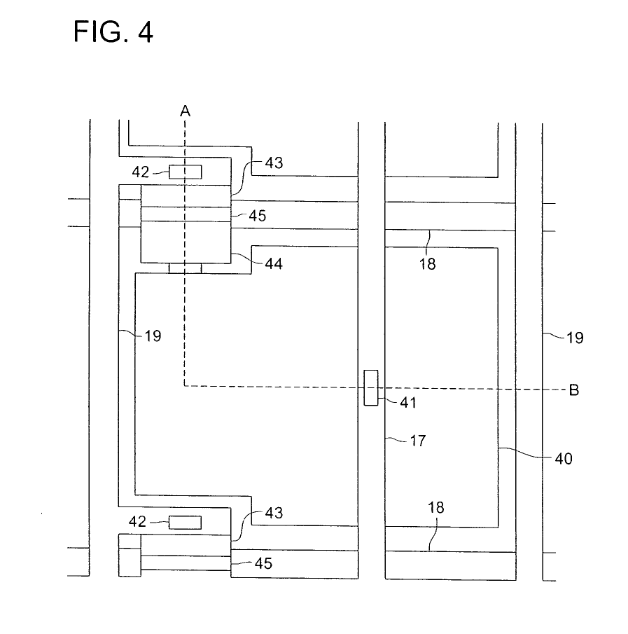

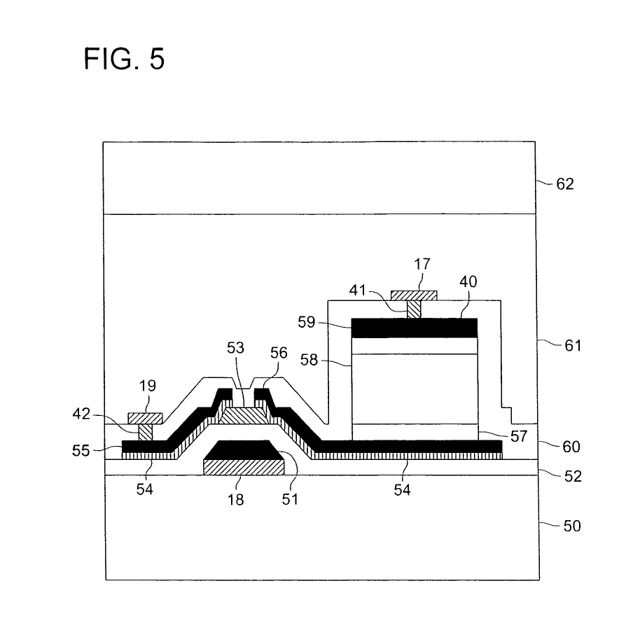

Further, the detecting element Gab has the structure as shown in the upper surface view of FIG. 4, and sectional view of FIG. 5. Initially, referring to the upper surface view of FIG. 4, the arrangement relationship between the photo diode 30 and TFT 31 will be described. The photo diode 30 is formed in the area surrounded by the signal wiring 19 of charge transfer lines 19-1-19-n vertically wired, and the gate wiring 18 of the line selection lines 18-1-18-m horizontally wired. This photo diode 30 is arranged in T-shaped form cut two corners on one hand signal wiring 19 side. Then, TFT 31 is formed in such a manner that the gate electrode is arranged on the gate wiring 18, in a area sounded by ground corner of the upside and downside adjoining photo diode 30 and the signal wiring 19.

When the photo diode 30 and TFT 31 are formed In this manner, the transparent electrode film 40 like as ITO film formed of indium zinc oxide is formed, and then, bias line 17 is wired, vertically in area between TFT 31 and the signal line 9. This bias line 17 is wired on the surface of the transparent electrode film 40, and when it is connected to the transparent electrode film 40 by a contact 41, it is electrically connected to the photo diode 30.

Further, the source area 43 which is a source electrode of TFT 31, is electrically connected to the signal wiring 19 by a contact 42. Further, in TFT 31, a drain area 44 which is a drain electrode, is electrically connected to the photo diode 30 in the lamination part, and a channel area 45 is formed between the source area 43 and the drain area 44, and this channel area 45 is arranged on right upper the gate wiring 18. That is, in its lamination structure, the gate area which is the gate electrode formed under the channel area 45 is formed on the surface of the gate wiring 18.

The photo diode 30 and TFT 31 formed in this manner, has the lamination structure as a sectional view of FIG. 5. The lamination structure of the photo diode 30 forming 1 detecting element and TFT 31, will be described, referring to the sectional view of FIG. 5. Hereupon, FIG. 5 is a sectional view when cut on line A-B in FIG. 4.

As shown in FIG. 5, the gate electrode layer 51 is formed on the surface of the gate wiring 18 in such a manner that it is electrically connected to the gate wiring 18 wired on the surface of glass substrate 50, and the insulation layer 52 covering the surface of this gate electrode layer 51 and the glass substrate 50, is formed. Further, on the surface of the insulation layer 52, the channel layer 53 which is the channel area is formed just upper the gate electrode 51, and an etching stop layer 54 is formed on the surface excepting a part of the channel layer 53 and the surface of the insulation film 52. Then, the etching stop layer 54 on the side near the signal wiring 19 is formed from the edge of the channel layer 53 to the signal wiring 19, the source electrode layer 55 is formed on its surface, and the etching stop layer 54 on the side far from the signal line 19, is formed from the edge of the channel layer 53 to the area forming the photo diode 30, and on its surface, the drain electrode layer 56 is formed. Further, on the surface of the source electrode layer 55, a contact 42 is formed, and though this contact 42, the layer is electrically connected to the signal wiring 19. In this manner, TFT 31 is formed.

On the one hand, in the area forming the photo diode 30, p type amorphous silicon layer 57, I type amorphous silicon layer 58, and n type amorphous silicon layer 59, are laminated in order, and the photo diode 30 which is pin type photo diode, is formed. Further, on the surface of n type amorphous silicon 59, the transparent electrode layer 40 by which the light is transmitted, and which becomes low resistance, is formed, on a part of the surface of this transparent electrode layer 40, the contact 41 is formed, and through this contact 41, it is electrically connected to the bias line 17. On the surface of the photo diode 30 and TFT 31 structured in this manner, when the inter layer insulation film 60 is formed, the electric connection of each layer forming the photo diode 30 and TFT 31 is inhibited. Then, to the surface of this inter layer insulation film 60, the bias line 17 and the signal wiring 19 are wired.

Further, on the surface of the inter layer insulation film 50 on which wired the bias line 17 and the signal wiring 19 are wired, a protective film layer 61 for equalizing

The concave and convex by the protective film layer formed on the glass substrate 50 is formed. This protective film layer 61 has a function that conducts the equalizing the lamination part of the glass substrate 50 upper part, and also protects the photo diode 30 and TFT 31 for forming the detecting element Gab, for example, by using the spin-coat engineering, when the photosensitive poly-imide or acrylic resin is coated, it is formed. Then, on the surface of this protective layer, for example, cesium iodide (CsI) is evaporated, and the scintillator layer 62 is formed. This scintillator layer 62 has a function for converting the incident radiation into the visible light. When made in this manner, FPD1 which becomes an indirect conversion system, can be structured. Hereupon, in the present example, the FPD which is an indirect conversion system, is listed as an example, but, the FPD which is a direct conversion system, may also be used.

### (1) THE FIRST EXAMPLE OF THE IMAGE PICKUP OPERATION IN FPD

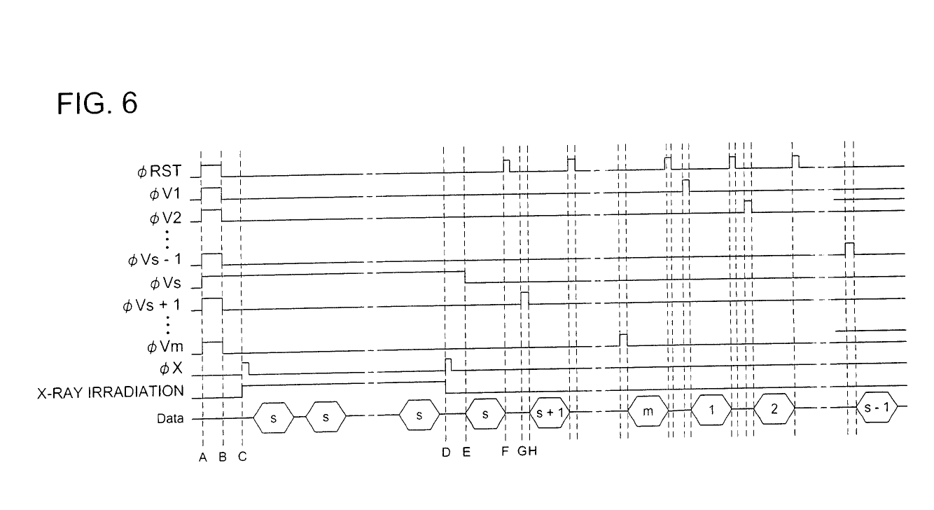

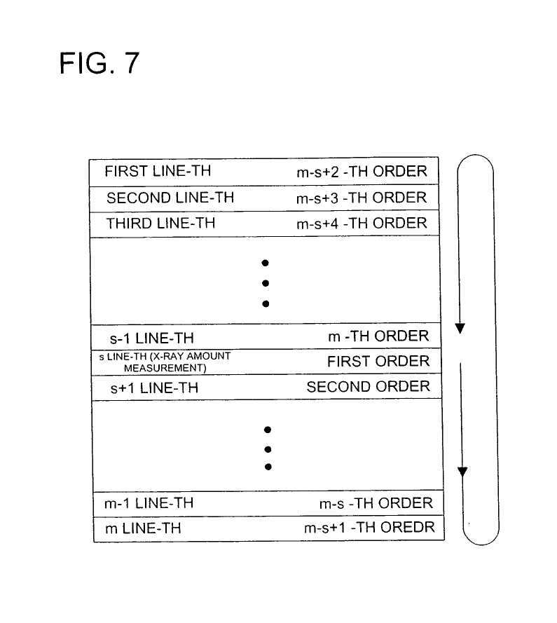

Referring to the drawings, the first example of the image pickup operation by FPD1 structured as described above, will be described. FIG. 6 is a timing chart showing the relationship between each signal and the outputted image data in FPD1. Further, FIG. 7 is a view showing the relationship between the in which the detecting element for X-ray amount measurement is aligned, and the order for each line for outputting the image data. Hereupon, as shown in FIG. 7, it is presumed that the image data based on the electric signal from the s line-th detecting element Gs1-Gsn, is used for the X-ray amount measurement.

Initially, in order to reset the anodes of the photo diode 30 of respective of detecting element G11-Gmn and the capacitors 33 of respective of the output circuits 13-1-13-n, the signal ΦV1-ΦVm and the signal ΦRST from the timing generator 16 are simultaneously made high (timing A). Hereby, the signal ΦV1-ΦVm which become high are given to the gate electrode of TFT 31 of respective of the detecting elements G11-Gmn, and become ON, and the signals ΦRST which become high are given to the switches 34 of respective of the output circuits 13-1-13-n, and become ON. Hereby, the reset operation of the anode of the photo diode 30 of respective of the detecting elements G11-Gmn and the capacitor 33 of respective of the output circuits 13-1-13-n is started.

Then, after a predetermined time passes, when a condition that the reset of the anode of the photo diode 30 of respective of the detecting elements G11-Gmn and the capacitor 33 of respective of the output circuits 13-1-13-n is enough, is realized, the signals ΦV1-ΦVs−1, ΦVs+1-ΦVm except of the signal ΦVs given to the detecting elements Gs1-Gsn for the X-ray measurement are made low, and the signal ΦRST given to the output circuits 13-1-13-n is made low (timing B). Hereupon, the signal ΦVs is remained high, and TFT 31 in detecting elements Gs1-Gsn is remained ON. After this time, it becomes a photographing possible condition. After that, the X-ray irradiation is started by the operation of an operator. Specifically, when the X-ray control signal ΦX which is a high pulse signal from the control section 5, is given to the X-ray tube 100 by the wireless or wire, the X-ray irradiation from the X-ray tube 100 is started (timing C).

When the X-ray irradiation is conducted from the X-ray tube 100, because X-ray is irradiated on detecting elements G11-Gmn, the photoelectric conversion operation is conducted by the photo diode 30, and the light electric charge corresponding to the incident X-ray amount is generated. Then, the detecting elements Gs1-Gsn to which the high signal ΦVs is given, because TFT 31 is made ON, and through the charge transfer lines 19-1-19-n, is electrically connected to the output circuits 13-1-13-n, the light electric charge generated in photo diodes 30 of respective of detecting elements Gs1-Gsn, is accumulated in respective capacitors 33 of the output circuits 13-1-13-n. Further, the detecting elements G11-G(S−1)n, G(S+1)1-Gmn to which the low signals ΦV1-Vs−1, ΦVs+1-ΦVm are given, because TFT 31 is made OFF, and it is a condition that it is electrically cut from the output circuit 13-1-13-n, the light electric charge is accumulated in the anodes of photo diodes 30 of respective of the detecting elements G11-G(S−1)n, G(S+1)1-Gmn.

At the time of this X-ray irradiation, for each predetermined interval T, the timing generator 16 drives the multiplexer 14 and the A/D conversion circuit 15. Accordingly, the electric signal which appears on the operation amplifier 32 of the output circuits 13-1-13-n every predetermined interval T is inputted into the multiplexer 14, and after it is converted into serial electric signal for each detecting element, it is converted into the image data which will be the digital data, in the A/D conversion circuit 15. That is, the electric signal which is the voltage value corresponding to the electric charge amount accumulated in the capacitor 33 of the output circuits 13-1-13-n , is given to the multiplexer 14, and the electric signal is outputted to the A/D conversion circuit 15 in the order of the output circuits 13-1, 13-2, . . . , 13-n, and converted into the image data which is the digital data.

This image data is the data in which the image data of respective of the detecting elements Gs1-Gsn expressing the X-ray amount incident on respective of detecting elements Gs1-Gsn is aligned serally. Then, when the image data of respective of the detecting elements Gs1-Gsn are outputted to the signal processing section 2, by conducting the addition averaging processing of the image data, the effective output value expressing the irradiated X-ray amount is obtained. Then, the obtained effective output value is given to the control section 5, and it is confirmed whether the value is more than a predetermined index value.

In this manner, the image data expressing the X-ray amount incident on respective of the detecting elements Gs1-Gsn, is outputted, however, the capacitor 33 of the output circuits 13-1-13-n, and the photo diode 30 of respective of the detecting elements Gs1-Gsn are not reset, and the electric charge are remained in the accumulated state. Accordingly, every time when the multiplexer 14 is driven every predetermined interval T, the electric signal by the light electric charge expressing the X-ray amount from when X-ray irradiation is started at the timing C is given to the multiplexer 14. Accordingly, the X-ray amount from when X-ray irradiation is started at the timing C can be confirmed in the signal processing section 2.

Then, while the multiplexer 14 and A/D conversion circuit 15 is operated plural times every predetermined interval T, in the control section 5, it is confirmed that the effective output value by the respective image data of the detecting elements Gs1-Gsn is more than a predetermined index value. Accordingly, because it is confirmed that the X-ray amount from the time when the X-ray irradiation is started, is the X-ray amount enough to image output, the control section 5 indicates the X-ray tube 100 that the irradiation of the X-ray is stopped. In this case, the control section 5 indicates the timing generator 16 of FPD1 so as to switch from the measurement operation to signal read-out operation.

Then, when the X-ray control signal ΦX which is a high pulse signal is given to the X-ray tube 100 from the control section 5, after the X-ray irradiation from the X-ray tube 100 is stopped (timing D), the reading-out of the image data obtained by image pickup is started. The order of the read-out line of the image data of this FPD1 is one shown in FIG. 7. Initially, the signal ΦVs given to the detecting elements Gs1-Gsn though the line selection signal 18-s from the perpendicular scanning circuit 12 is made low (timing E). As described above, TFT 31 of respective of the detecting elements Gs1-Gsn is made OFF, and after it is made a condition that the light electric charge is accumulated in the capacitor 33, by the timing generator 16, the multiplexer 14 and A/D conversion circuit 15 are made ON, and the image data of respective of the detecting elements Gs1-Gsn are outputted to the signal processing section 2.

After that, when the pulse signal ΦRST which will be high is given to the output circuits 13-1-13-n through the reset line 20 from the timing generator 16, the capacitor 33 of the output circuits 13-1-13-n is reset (timing F). Then, after the signal ΦRST is made low, when the pulse signal ΦVs+1 is given to the detecting elements G(s+1)-G(s+1)n through the line selection signal 18-(s+1) from the perpendicular scanning circuit 12, in the detecting elements G(s+1)-G(s+1)n, TFT 31 is made ON and the light electric charge accumulated in the photo diode 30 is introduced to respective of the charge transfer line 19-1-19-n (timing G). Hereby, in the capacitor 32 of respective of the output circuits 13-1-13-n, the light electric charge accumulated in respective photo diode 30 is accumulated. When this signal ΦVs+1 is low, the multiplexer 14 and A/D conversion circuit 15 are made ON, the image data of respective of the detecting elements G(s+1)-G(s+1)n is outputted to the signal processing section 2 (timing H).

When the image data of respective of s+1 line-th detecting elements G(s+1)-G(s+1)n is outputted, in the order of ΦRST, ΦVs+2 which will be high, from the timing generator 16 and the perpendicular scanning circuit 12, after the capacitor 33 of respective of the output circuits 13-1-13-n is reset, the light electric charge accumulated in the photo diode 30 of respective of the detecting elements G(s+2)1-G(s+2)n is accumulated in the capacitor 33 of respective of the output circuits 13-1-13-n. Then, the image data of respective of the s+2 line-th detecting elements G(s+2)1-G(s+2)n is outputted to the signal processing section 2.

After that, in the same manner, the signal ΦRST, and the signal ΦVs+3-ΦVm, are alternately outputted as the pulse signal which will be high, as shown in FIG. 7, s+3 line-th-m line-th detecting elements G(s+3)1-Gmn are operated every line, and the image data of the detecting elements G(s+3)1-Gmn are outputted to the signal processing section 2. Then, when the image data of m line-th detecting elements Gm1-Gmn are outputted, the signal ΦRST from the timing generator 16 and the signal ΦV1-ΦVs−1 from the perpendicular scanning circuit 12 are alternately outputted as the pulse signal which will be high, as in FIG. 7, the detecting elements G11-G(s−1)n of 1 line-th-s−1 line-th are operated every line and the image data of the detecting elements G11-G(s−1)n are outputted to the signal processing section 2.

In this manner, in the present example, the X-ray amount irradiated by the respective image data of s line-th detecting elements Gs1-Gsn is measured, and when the X-ray amount is more than a predetermined index amount, initially, to the detecting elements Gs1-Gsn, the read-out operation of the image data is conducted every line in order from s line-th to m line-th. Then, after the image data of m line-th detecting elements Gm1-Gm n is read out, to the detecting elements G11-G(s−1)n, the read-out operation of the image data is conducted every line in order from 1-line to s−1 line-th.

### (2) THE SECOND EXAMPLE OF THE IMAGE PICKUP OPERATION IN FPD

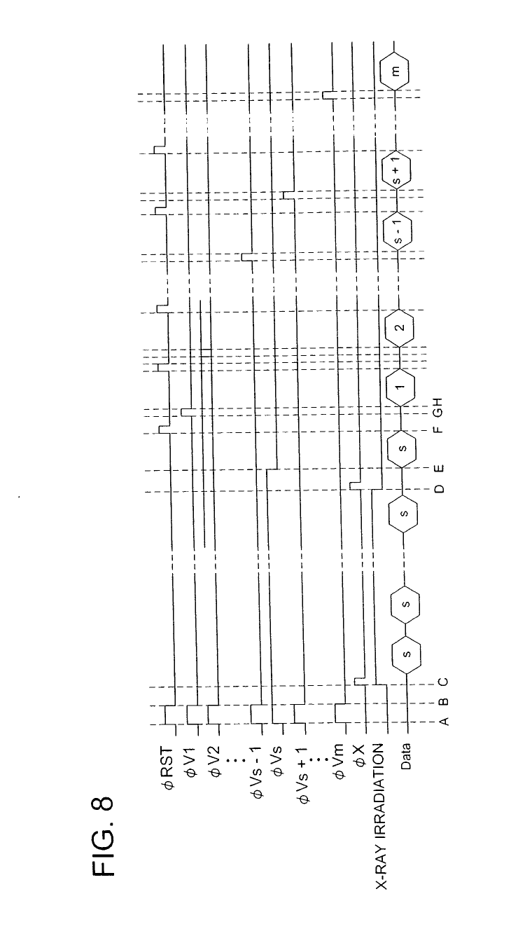

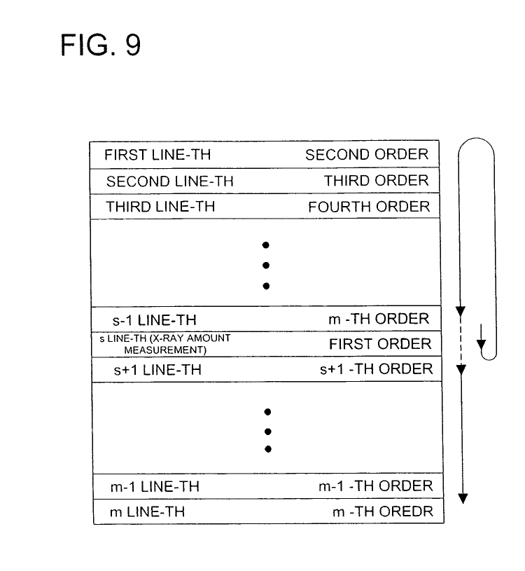

The second example of the image pickup operation in FPD structured as described above, will be described referring to the drawings. FIG. 8 is a timing chart showing the relationship among each signal in FPD1 and outputted image data. Further, FIG. 9 is a view showing the relationship between the line in which the detecting elements for X-ray amount measurement are aligned, and the order for each line for outputting the image data.

Also in the present example, in the same as the above-described first example, initially, after the signal ΦRST, ΦV1-ΦVm are made high simultaneously, and the capacitor 33 of the photo diode 30 of the detecting elements G11-Gmn and the output circuits 13-1-13-n are reset, the signals except of the signal ΦVs are made low, and the X-ray control signal ΦX is given to the X-ray tube 100 from the control section 5, and the X-ray irradiation by the X-ray tube 100 is started (timing A-C). Then, while the X-ray irradiation from the X-ray tube 100 is conducted, every predetermined interval T, the multiplexer 14 and A/D conversion circuit 15 are driven, the image data expressing the X-ray amount incident on respective of the detecting elements Gs1-Gsn is outputted to the signal processing circuit 2, and in the control section 5, it is confirmed whether the effective output value by the respective image data of the detecting elements Gs1-Gsn is more than a predetermined index value.

In this manner, when the X-ray amount is confirmed by the respective image data of the detecting elements Gs1-Gsn at the time of the X-ray irradiation, and the control section 5 confirms that the effective output value by the respective image data of the detecting elements Gs1-Gsn is more than a predetermined index value, in the same as the first example, the X-ray control signal ΦX is given to the X-ray tube 100 by the control section 5, and after the X-ray irradiation by the X-ray tube 100 is stopped, the signal ΦVs given to the detecting elements Gs1-Gsn is mad low (timing D, E), the respective image data of the detecting elements Gs1-Gsn are outputted to the signal processing section 2.

After that, in the case where the pulse signal ΦRST which will be high, is given from the timing generator 16 to the output circuits 13-1-13-n through the rest line 20, when the capacitor 33 of the output circuit 13-1-13-n is reset (timing F), different from the first example, the pulse signal ΦV1 which will be high, is given to the detecting elements G11-G1n through the line selection signal 18-1 from the perpendicular scanning circuit 12 (timing G). Hereby, in the detecting elements G11-G1n, TFT 31 is made ON, the light electric charge accumulated in the photo diode 30 is introduced to the respective of the charge transfer lines 19-1-19-n, and accumulated in the respective capacitors 33 of the output circuits 13-1-13-n. After this signal ΦV1 is made low, the multiplexer 14 and A/D conversion circuit 15 are made ON, and the image data of the respective detecting elements G11-G1n is outputted to the signal processing section 2 (timing H).

After that, in the same manner, the signal ΦRST from the timing generator 16 and the signal ΦV2-ΦVs−1 from the perpendicular scanning circuit 12 are alternately outputted as the pulse signal which will be high, and as in FIG. 9, the second line-th-s−1 line-th detecting elements G21-G(s−1)n of are operated every line, and the image data of the detecting elements G(s−1)1-G(s−1)n is outputted to the signal processing section 2. Then, when the image data of s−1 line-th detecting elements G(s−1)1-G(s−1)n is outputted, the signal ΦRST from the timing generator 16 and the signals ΦVs+1-ΦVm from the perpendicular scanning circuit 12 are alternately outputted as the pulse signal which will be high, and as in FIG. 9, s+1 line-th-m line-th detecting elements G(s+1)1-Gmn are operated every line, and the image data of the detecting elements G(s+1)1-Gmn is outputted to the signal processing section 2.

In this manner, in the present example, the X-ray amount irradiated by the image data of the respective of s line-th detecting elements Gs1-Gsn is measured, and when the X-ray amount is more than a predetermined index value, initially, after the read-out operation of the image data of s line-th detecting elements Gs1-Gsn is conducted, to the detecting elements G11-G(s−1)n, the read-out operation of the image data in order from 1 line to s−1 line is conducted every line. Then, after the read-out of the image data of s−1 line-th detecting elements G(s−1)1-G(s−1)n is conducted, to the detecting elements G(s+1)1-Gmn, the read-out operation of the image data is conducted in order from s+1 line to m line every line.

### (3) THE THIRD EXAMPLE OF THE IMAGE PICKUP OPERATION IN FPD

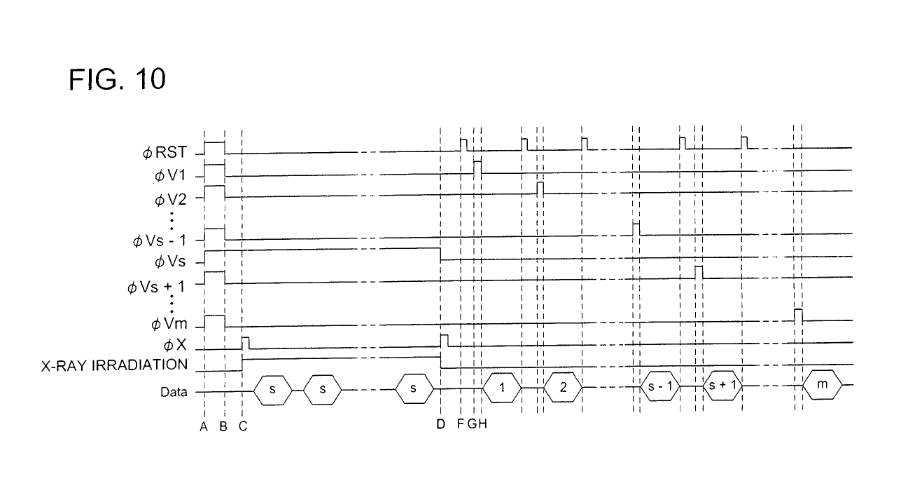

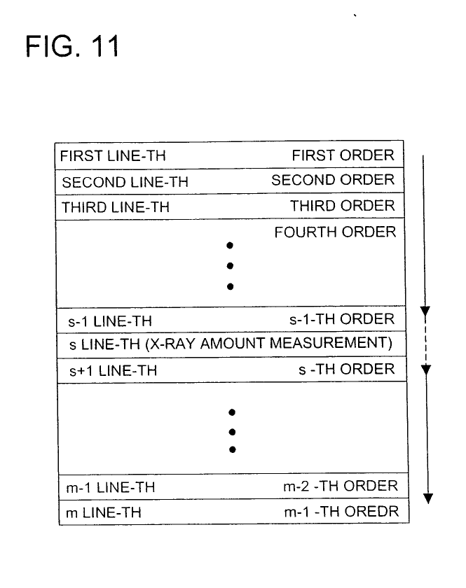

The third example of the image pickup operation by FPD1 structured as described above, will be described referring to the drawings. FIG. 10 is a timing chart showing the relationship among each of signals in FPD1 and the outputted image data. Further, FIG. 11 is a view showing the relationship between the line in which the detecting elements for the X-ray amount measurement are aligned, and the order for each line for outputting the image data.

Also in the present example, in the same as the above-described second example, initially, after the signal ΦRST, ΦV1-ΦVm are made high simultaneously, and the capacitors 33 of the photo diode 30 of the detecting elements G11-Gmn and the output circuits 13-1-13-n are reset, the signals except of the signal ΦVs are made low, and the X-ray control signal ΦX is given to the X-ray tube 100 from the control section 5, and the X-ray irradiation by the X-ray tube 100 is started (timing A-C). Then, while the X-ray irradiation from the X-ray tube 100 is conducted, every predetermined interval T, the multiplexer 14 and A/D conversion circuit 15 are driven, and the image data expressing the X-ray amount incident on respective of the detecting elements Gs1-Gsn is outputted to the signal processing circuit 2, and in the control section 5, it is confirmed whether the effective output value by the respective image data of the detecting elements Gs1-Gsn is more than a predetermined index value.

In this manner, when the X-ray amount is confirmed by the respective image data of the detecting elements Gs1-Gsn at the time of the X-ray irradiation, and the control section 5 confirms that the effective output value by the respective image data of detecting elements Gs1-Gsn is more than a predetermined index value, in the same manner as the first example, the X-ray control signal ΦX is given to the X-ray tube 100 by the control section 5, and the X-ray irradiation by the X-ray tube 100 is stopped (timing D). In this case, different from the second example, at the same time as the stoppage of X-ray irradiation, the signal ΦVs given to the detecting elements Gs1-Gsn is made low.

After that, in the case where the pulse signal D)RST which will be high, is given from the timing generator 16 to the output circuits 13-1-13-n through the rest line 20, when the capacitor 33 of the output circuit 13-1-13-n is reset (timing F), the pulse signal ΦV1 which will be high, is given to the detecting elements G11-G1n through the line selection signal 18-1 from the perpendicular scanning circuit 12 (timing G). Hereby, the image data of the respective detecting elements G11-G1n is outputted to the signal processing section 2 (timing H).

After that, in the same manner, the signal ΦRST from the timing generator 16 and the signal ΦV2-ΦVs−1 from the perpendicular scanning circuit 12 are alternately outputted as the pulse signal which will be high, and as in FIG. 11, the second line-th-s−1 line-th detecting elements G21-G(s−1)n are operated every line, and the image data of the detecting elements G21-G(s−1)n is outputted to the signal processing section 2. Then, when the image data of s−1 line-th detecting elements G(s−1)1-G(s−1)n is outputted, the signal ΦRST from the timing generator 16 and the signals ΦVs+1-ΦVm from the perpendicular scanning circuit 12 are alternately outputted as the pulse signal which will be high, and as in FIG. 11, s+1 line-th-m line-th detecting elements G(s+1)1-Gmn are operated every line, and the image data of the detecting elements G(s+1)1-Gmn is outputted to the signal processing section 2.

In this manner, in the present example, the X-ray amount irradiated by the image data of the respective of s line-th detecting elements Gs1-Gsn is measured, and when the X-ray amount is more than a predetermined index value, different from the second example, the read-out operation of the image data of s line-th detecting elements Gs1-Gsn is not conducted, initially, to the detecting elements G11-G(s−1)n, the read-out operation of the image data in order from 1 line to s−1 line is conducted every line. Then, after the read-out of the image data of s−1 line-th detecting elements G(s−1)1-G(s−1)n is conducted, to the detecting elements G(s+1)1-Gmn, the read-out operation of the image data is conducted in order from s+1 line to m line every line.

Hereupon, in the present example, as in the second example, the read-out of the image data is conducted in such a manner that after the measurement of X-ray amount by the s line-th detecting elements Gs1-Gsn, in the order from 1 line-th detecting elements G11-G1n, the image data of the detecting elements G11-G(s−1)n, G(s+1) -Gmn except of s line-th detecting elements Gs1-Gsn is outputted, however, in the same as the first example, in the order from the image data of s+1 line-th detecting elements G(s+1)1-G(s+1)n, the image data of detecting elements G11-G(s−1)n, G(s+1)1-Gmn may be outputted. In this case, after the read-out operation every line to the detecting elements G(s+1)1-Gmn is conducted, further, the read-out operation every line to the detecting elements G11-G(s−1)n is conducted.

Further, in the present example, for the image data of s line-th detecting elements Gs1-Gsn for the X-ray amount measurement for which the image data is not read out, in the signal processing section 2, when the interpolation processing based on the image data of the adjoining s−1, s+1 line-th respective detecting elements G(s−1)1-G(s−1)n, G(s+1)1-G(s+1)n is conducted, it may also be generated.

Further, as in the first example, and second example, when the image data of all detecting elements G11-Gmn including also s line-th detecting elements Gs1-Gsn for the X-ray amount measurement is read out, the image data of s line-th detecting elements Gs1-Gsn for the X-ray amount measurement may also be discarded. In this case, for the image data of s line-th detecting elements Gs1-Gsn, when the interpolation processing based on the image data of the adjoining s−1, s+1 line-th respective detecting elements G(s−1)1-G(s−1)n, G(s+1)1-G(s+1)n is conducted, it may also be generated.

Hereupon, in the radiation image pickup apparatus 101, when FPD1 conducts photographing operation, for s line-th detecting elements Gs1-Gsn for measuring the X-ray amount, it may also be fixed, or it may also be switched to another line for each photographing. When switched to another line for each photographing, corresponding to the subject, the optimum line is set, and it is indicated so that the X-ray amount is measured by the detecting elements of set line.

Further, when s line-th detecting elements Gs1-Gsn for measuring the X-ray amount is switched, faint X-ray or visible light is irradiated on the status that the subject is fixed before FPD1, and when the position and size of the subject to the photographing area in FPD1 is confirmed, s line-th detecting elements Gs1-Gsn for measuring the X-ray amount may also be set.

That is, when the visible light having the sensitivity to the faint X-ray or photo diode 30 is irradiated and the position and size of the subject are confirmed, actually, 1 frame image is photographed by FPD1. Then, the position at which the detecting element in which the value of the image data obtained by photographing is less than a predetermined value, continues is confirmed as a position at which the subject is arranged, and the position and size of the subject to the detecting elements G11-Gmn constituting the sensor section 11 are confirmed. Then, based on the position and size of the subject to the detecting elements G11-Gmn of the confirmed sensor section 11, s line-th detecting elements Gs1-Gsn which is optimum for measuring the X-ray amount is set.

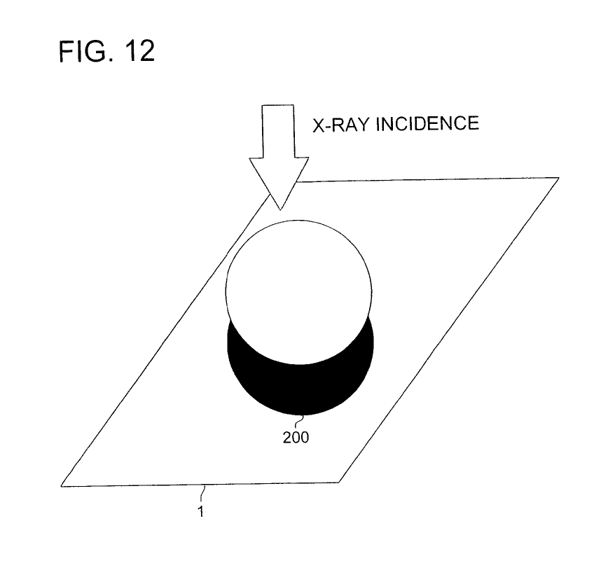

Further, when the visible light is irradiated and the position and size of the subject are confirmed, as in FIG. 12, by a shadow 200 projected on the surface of FPD1, the position and size of the subject to the detecting elements G11-Gmn constituting the sensor section 11 are confirmed. In this case, on the surface of FPD1, a mark which is a rough aim expressing the position of each line of detecting elements G11-Gmn of the sensor section 11 is marked, and by the relationship between this mark and the shadow 200, the position and size of the subject to the detecting elements G11-Gmn of the sensor section 11 are confirmed. Then, based on the position and size of the subject to the detecting elements G11-Gmn of the confirmed sensor section 11, the s line-th detecting elements Gs1-Gsn which is optimum for measuring the X-ray amount is set.

In this manner, when the faint X-ray and visible light are irradiated under the condition that the subject is fixed before FPD1, the position and size of the subject to the photographing area in FPD1 are confirmed, by the confirmed position and size of the subject, the range for irradiating the X-ray may be set.

Further, all of the above-described s line-th detecting elements Gs1-Gsn are used as the detecting element for measuring the X-ray amount, however, it is not necessary that all of 1 line detecting elements are made the detecting element for measuring the X-ray amount, and a plurality of detecting elements in the s line-th detecting elements Gs1-Gsn may also be used. Further, in the signal processing section 2, when the addition averaging processing of the image data of s line-th detecting elements Gs1-Gsn is conducted, the effective output value expressing the irradiated X-ray amount is obtained, however, the maximum output value of the image data of s line-th detecting elements Gs1-Gsn is detected, and this maximum output value may also be made the effective output value expressing the irradiated X-ray value.

### The Second Embodiment

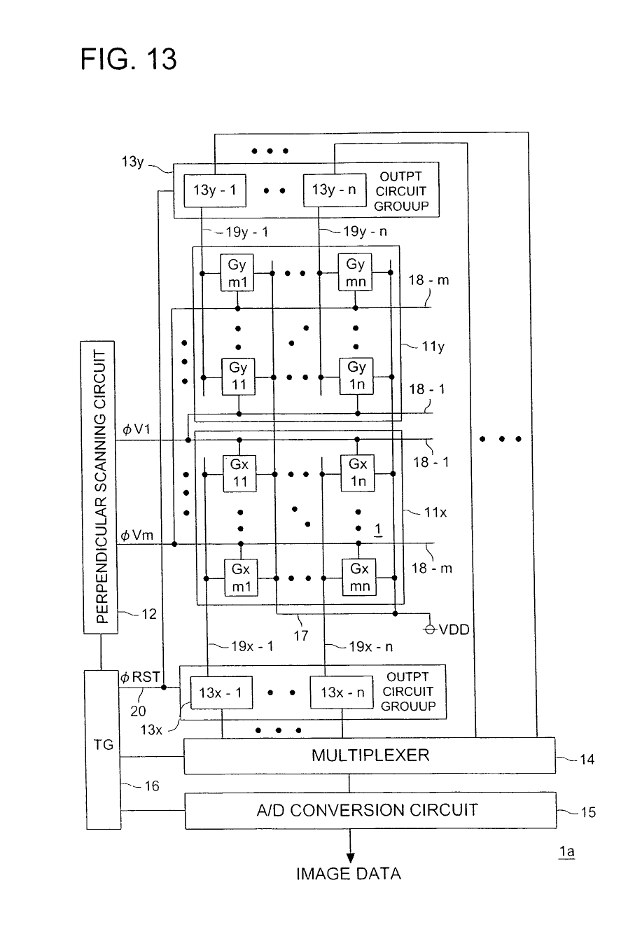

Referring to the drawings, the second embodiment of the present invention will be described. FIG. 13 is an outline block diagram showing the internal structure of FPD in the radiation image pickup apparatus of the present embodiment. Hereupon, the structure of the detecting elements and output circuits provided in FPD shown in FIG. 13 is, in the same as the first embodiment, the structure in FIG. 3.

FPD1a in the radiation image pickup apparatus of the present embodiment provides, as shown in FIG. 13, a sensor section 11x providing m line n row detecting elements Gx11-Gxm, and sensor section 11y providing m line n row detecting elements Gy11-Gymn, and output circuit group 13x by output circuits 13x-1-13x-n holding for each line the electric signal outputted from each detecting element Gx11-Gxmn of the sensor section 11, and output circuit group 13y by the output circuit 13-y-13y-n holding for each line the electric signal outputted from each detecting element Gy11-Gymn of the sensor section 11, a perpendicular scanning circuit 12, multiplexer 14, A/D conversion circuit 15, and timing generator 16. In this case, the detecting element Gx11-Gxmn, Gy11-Gymn are structured so that each detecting element of 1-n rows of the sensor section 11x and each detecting element of 1-n rows of the sensor section 11y are arranged in the same row.

This FPD1a provides a bias line 17 by which the DC voltage VDD is impressed on respective of detecting elements Gx11-Gxmn, Gy11-Gymn, a line selection line 18-1-18-m provided every same 1 line of the sensor section 11x, 11y for giving the signal ΦV1-ΦVm given from the perpendicular scanning circuit 12 to for each line to the detecting element of each line in the respective of the sensor section 11x, 11y, and the charge transfer line 19x-1-19x-n, 19y-1-19y-n provided every row for outputting the electric signal from the detecting element in each of the sensor sections 11x, 11y to each of output circuits 13x, 13y every row, and the reset line 20 for giving the reset signal ΦRST which resets all detecting elements of the sensor sections 11x, 11y, and output circuit group 13x, 13y, to the output circuit group 13x, 13y.

When each line is wired in this manner, to the line selection line 18-k (k is integer of 1≦k≦m), the detecting elements Gxk1-Gxkn, Gyk1-Gykn are connected, and the signal ΦVk is given from the perpendicular scanning circuit 12. When the signal ΦVk is given and the image data of the detecting elements Gxk1-Gxkn, Gyk1-Gykn is outputted, the light electric charge accumulated in respective detecting elements Gxk1-Gxkn, Gyk1-Gykn is accumulated in the respective output circuits 13x-1-13x-n, 13y-1-13y-n. Then, after the electric signal of respective output circuits 13x-1-13x-n, 13y-1-13y-n is given to the multiplexer 14, the electric signal is given every 1 detecting element to the A/D conversion circuit 15, and outputted to the signal processing section 2 as the image data which is the digital data. Hereupon, among the timing generator 16, perpendicular scanning circuit 12, multiplexer 14, and A/D conversion circuit 15, or also between the multiplexer 14 and the A/D conversion circuit 15, the signal line for sending and receiving the signal is connected, however, its detailed description is omitted.

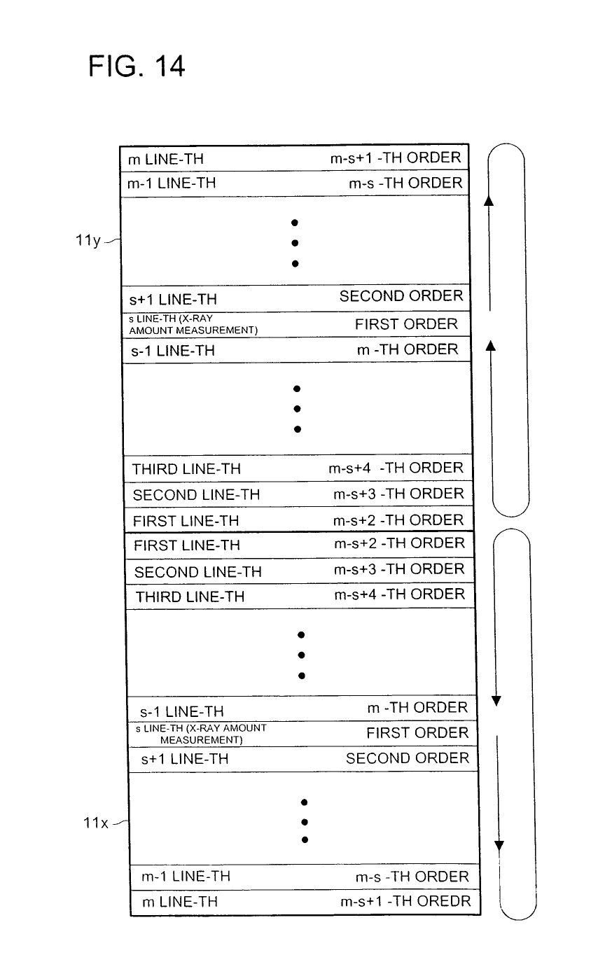

In this FPD1a, in the case where s line-th detecting elements Gxs1-Gxsn, Gys1-Gysn of respective sensor sections 11x, 11y is the detecting element for the X-ray amount measurement at the time of the x-ray irradiation, when the same operations as in the first-third example in the first embodiment, is conducted, the photographing operation in which the x-ray amount measurement is conducted, can be conducted. In this case, for example, when operated as in the first example, in the same manner as in the first embodiment, the relationship between the signal ΦRST, and ΦV1-ΦVn becomes a situation shown in the timing chart of FIG. 6. Accordingly, the relationship between the line in which the detecting element for the X-ray amount measurement is aligned, and the order for each line for outputting the image data becomes a situation shown in FIG. 14.

That is, as shown in FIG. 14, when the x-ray amount is measured by the image data of s line-th detecting elements Gxs1-Gxsn, Gys1-Gysn of respective sensor sections 11x, 11y, and it is confirmed that it is more than a predetermined index value, the read-out operation of the image data of s line-th-m line-th detecting elements Gxs1-Gxmn, Gys1-Gymn of respective sensor sections 11x, 11y is conducted every 1 line in the order from s line. Then, when the image data of m line-th detecting elements Gxm1-Gxmn, Gym1-Gymn of respective sensor sections 11x, 11y, is outputted, next, the read-out operation of the image data of 1 line-th-s-1 line-th detecting elements Gx11-Gx(s−1)n, Gy11-Gy(s−1)n of respective sensor sections 11x, 11y is conducted every 1 line in the order from 1 line.

When operated in this manner, when the image data of s line-th detecting elements Gxs1-Gxsn, Gys1-Gysn is outputted and the measurement X-ray amount is conducted, in the signal processing section 2, when the addition averaging processing of the image data of s line-th detecting elements Gxs1-Gxsn, Gys1-Gysn is conducted, the effective output value expressing the irradiated X-ray amount is obtained. For the effective output value expressing the irradiated X-ray amount, it may also be the maximum value of the image data of s line-th detecting elements Gxs1-Gxsn, Gys1-Gysn.

Hereupon, in the present embodiment, the sensor section is divided by 2 into the sensor sections 11x, 11y, the detecting elements Gxs1-Gxsn, Gys1-Gysn for the X-ray amount measurement for 2 lines are provided, however, the line of detecting elements connected to charge transfer lines 19x-1-19x-n, 19y-1-19y-n connected to respective output circuits 13x-1-13x-n , 13y-1-13y-n may also be alternately arranged. Further, it is not limited to the detecting elements for the X-ray amount measurement for 2 lines, but the detecting elements for the X-ray amount measurement for x lines (x is integer more than 3) more than 3 lines, may also be provided. In this case, x groups of the output circuit group by n output circuits connected to respective detecting elements for the x-ray amount measurement for x lines are arranged.

Further, in the present embodiment, as in the third example, when the operation by which the read-out of the image data of s line-th detecting elements Gxs1-Gxsn, Gys1-Gysn for X-ray amount measurement is not conducted, is conducted, as same as in the first embodiment, in the signal processing section 2, when the interpolation processing based on the image data of respective adjoining s−1, s+1 line-th detecting elements Gx(s−1)1-Gx(s−1)n, Gx(s+1)1-Gx(s+1)n is conducted, the image data of the detecting elements Gxs1-Gxsn is generated, further, when the interpolation processing based on the image data of respective adjoining s−1, s+1 line-th detecting elements Gy(s−1)1-Gy(s−1)n, Gy(s+1)1-Gy(s+1)n is conducted, the image data of the detecting elements Gys1-Gysn may also be generated.

Furthermore, as in the first example and the second example, when the image data of all detecting elements Gx11-Gxmn, Gy11-Gymn including also s line-th detecting elements Gxs1-Gxsn, Gys1-Gysn is read out, the image data of s line-th detecting elements Gxs1-Gxsn, Gys1-Gysn for X-ray amount measurement may also be discarded. In this case, for the image data of respective s line-th detecting elements Gxs1-Gxsn, Gys1-Gysn, when the interpolation processing based on the image data of adjoining (s−1)line-th detecting elements Gx(s−1)1-Gx(s−1)n, Gy(s−1)1-Gy(s−1)n and s+1 line-th respective detecting elements Gx(s+1)1-Gx(s+1)n, Gy(s+1)1-Gy(s+1)n is conducted, it may also be generated.

### The Third Embodiment

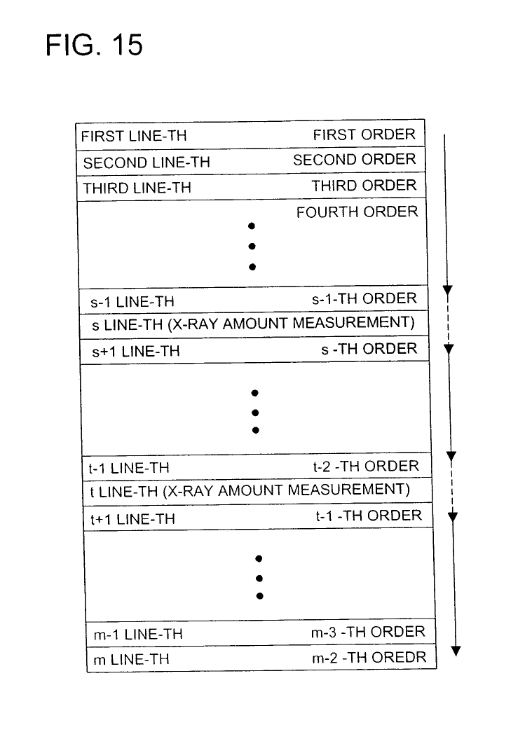

Referring to the drawings, the third embodiment of the present invention will be described. FIG. 15 is a view showing The relationship between the line in which the detecting element is aligned for the x-ray amount measurement in the radiation image pick-up apparatus of the present embodiment and the order for each line which outputs the image data. Hereupon, for the structure of FPD in the radiation image pickup apparatus of the present embodiment, and the structure of the detecting element provided in FPD, and the output circuit, as same as in the first embodiment, it is the structure shown in FIG. 2 and FIG. 3.

In the present embodiment, as shown in FIG. 15, different from the first embodiment, as the detecting element for the X-ray amount measurement at the time of the X-ray irradiation, not only s line-th detecting elements Gs1-Gsn is used, but also t line-th detecting elements Gt1-Gtn is used as the detecting element for X-ray amount measurement. That is, the X-ray amount measurement at the time of the X-ray irradiation, is conducted by the image data from s line-th and t line-th respective detecting elements Gs1-Gsn, Gt1-Gtn, and in respective output circuits 13-1-13-n, the electric charge for 2 detecting elements is held in the capacitor 33, and to the signal processing section 2, the image data to which the image data for 2 detecting elements is added is outputted.

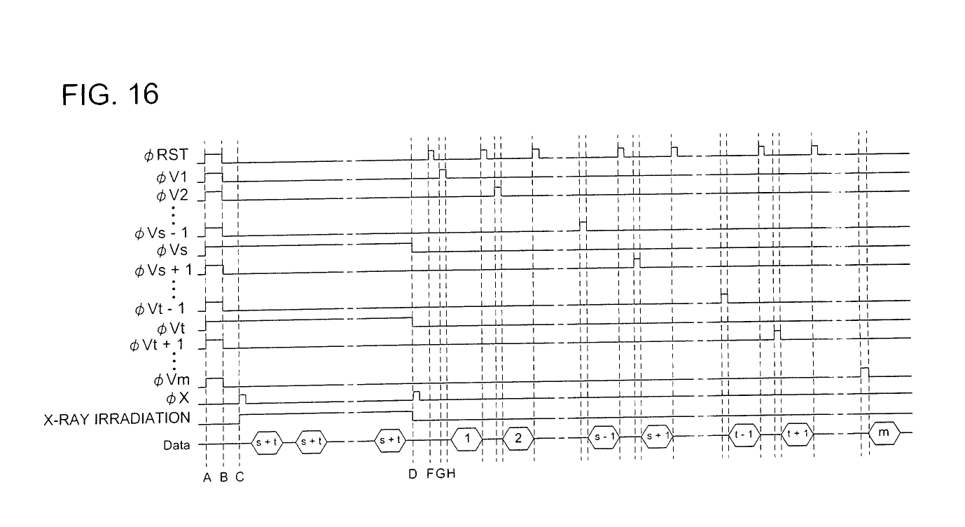

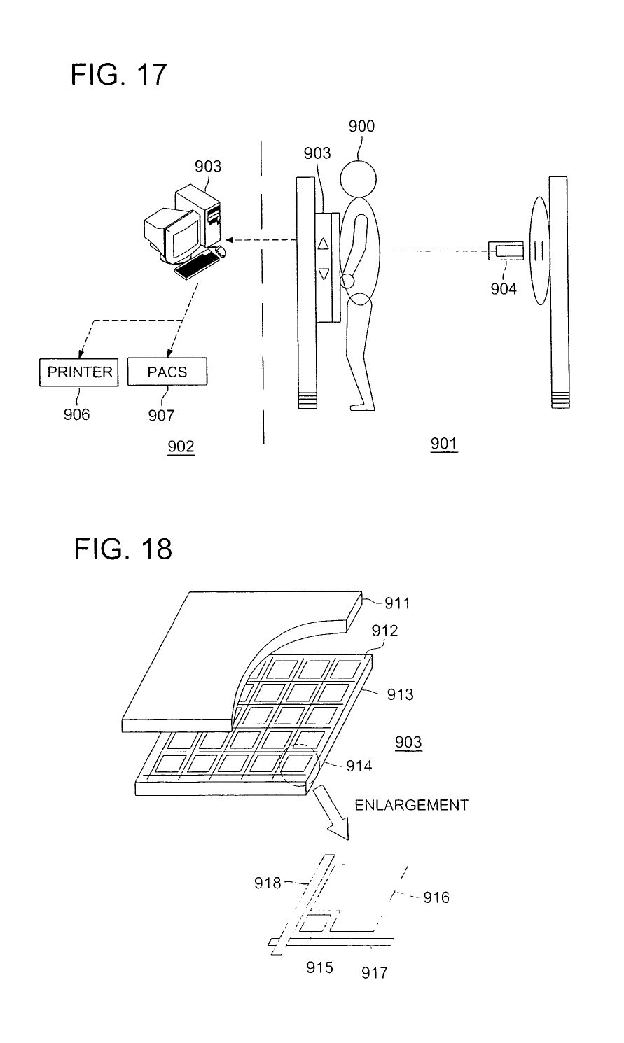

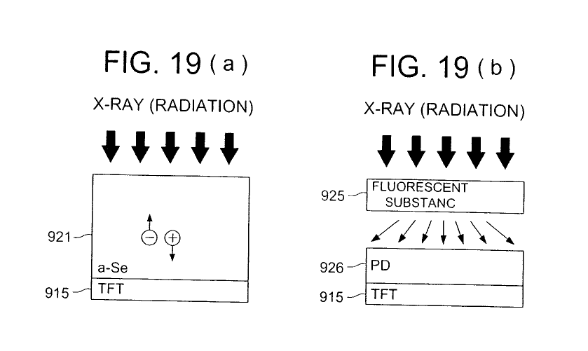

Accordingly, the image pickup operation in FPD1 of the radiation image pickup apparatus of the present embodiment, is the operation according to the timing chart of FIG. 16. Hereupon, this image pickup operation is the operation similar to the third example of the first embodiment. That is, initially, the signals ΦRST, ΦV1-ΦVn are made high, and after the photo diode 30 of detecting elements G11-Gmn and capacitor 33 of the output circuit 13-1-13-n are reset (timing A), the signals except ΦVs, ΦV1 are made low, and TFT 31 of the detecting element except the detecting element Gs1-Gsn, Gt1-Gtn is made OFF (timing B). After that, the X-ray control signal ΦX is given to the X-ray tube 100 from the control section 5, and the X-ray irradiation by the X-ray tube 100 is started (timing C).

Then, while the X-ray irradiation from the X-ray tube 100 is conducted, every predetermined interval T, the multiplexer 14 and A/D conversion circuit 15 are driven, and the image data expressing the X-ray amount incident on respective s line-th and t line-th detecting elements Gs1-Gsn, Gt1-Gtn is outputted to the signal processing section 2, and in the control section 5, it is confirmed whether the effective output value by the image data of respective detecting elements Gs1-Gsn, Gt1-Gtn is more than a predetermined index value. Hereupon, in the capacitor 33 of respective output circuits 13-1-13-n, the electric charge for 2 detecting elements is accumulated, and because the electric signal for 2 detecting elements is outputted, there is a possibility that the output value from respective output circuits 13-1-13-n is saturated. Therefore, it is preferable that a gain of respective output circuits 13-1-13-n is lowered comparing to the first and the second embodiments.

In this manner, when the X-ray amount is confirmed by the respective image data of the detecting elements Gs1-Gsn at the time of the X-ray irradiation, and the control section 5 confirms that the effective output value by the respective image data of detecting elements Gs1-Gsn, Gt1-Gtn is more than a predetermined index value, the X-ray control signal ΦX is given to the X-ray tube 100 by the control section 5, and the X-ray irradiation by the X-ray tube 100 is stopped (timing D). In this case, in the signal processing section 2, when the addition averaging processing of image data of s, t line-th detecting elements Gs1-Gsn, Gt1-Gtn is conducted, the effective output value expressing the irradiated X-ray amount is obtained. For the effective output value expressing this irradiated X-ray amount, it may also be the maximum value in the image data for 2 detecting elements of each row. Further, at the same time as the stoppage of X-ray irradiation, the signal ΦVs given to the detecting elements Gs1-Gsn, Gt1-Gtn is made low.

After that, in the case where the pulse signal ΦRST which will be high, is given from the timing generator 16 to the output circuits 13-1-13-n through the rest line 20, after the capacitor 33 of the output circuit 13-1-13-n is reset (timing F), the pulse signal ΦV1 which will be high, is given to the detecting elements G11-G1n through the line selection signal 18-1 from the perpendicular scanning circuit 12 (timing G). Hereby, the image data of the respective detecting elements G11-G1n is outputted to the signal processing section 2 (timing H).

After that, in the same manner, the signal ΦRST from the timing generator 16 and the signal ΦV2-ΦVs−1 from the perpendicular scanning circuit 12 are alternately outputted as the pulse signal which will be high, and as in FIG. 15, the second line-th-s−1 line-th detecting elements G21-G(s−1)n are operated every line, and the image data of the detecting elements G21-G(s−1)n is outputted to the signal processing section 2. Then, when the image data of s−1 line-th detecting elements G(s−1)1-G(s−1)n is outputted, the signal ΦRST from the timing generator 16 and the signals ΦVt+1-ΦVm from the perpendicular scanning circuit 12 are alternately outputted as the pulse signal which will be high, and as in FIG. 15, t+1 line-th-m line-th detecting elements G(t+1)1-Gmn are operated every line, and the image data of the detecting elements G(t+1)1-Gmn is outputted to the signal processing section 2.

In this manner, in the present embodiment, the X-ray amount irradiated by the image data for every 2 detecting elements of the respective of s line-th and t line-th detecting elements Gs1-Gsn, Gt1-Gtn is measured, and when the X-ray amount is more than a predetermined index value, the read-out operation of the image data of detecting elements Gs1-Gsn, Gt1-Gtn is not conducted, initially, to the detecting elements G11-G(s−1)n, the read-out operation of the image data in order from 1 line to s−1 line is conducted every line. Then, after the read-out of the image data of s−1 line-th detecting elements G(s−1)1-G(s−1)n is conducted, to the detecting elements G(s+1)1-G(t−1)n, the read-out operation of the image data is conducted in order from s+1 line to t−1 line every line.

Hereupon, in the present embodiment, after the X-ray amount irradiated by the image data for respective 2 detecting elements of respective detecting elements Gs1-Gsn, Gt1-Gtn is measured, the output of the image data is conducted in the order from 1 line, however, to the detecting elements except the detecting elements Gs1-Gsn, Gt1-Gtn, the output of the image data may also be conducted in order from s+1 line, or t+1 line. Further, as the operation of the first example and second example of the first embodiment, after the X-ray amount irradiated by the image data for respective 2 detecting elements of the detecting elements Gs1-Gsn, Gt1-Gtn is measured, after all image data of the detecting elements G11-Gmn are outputted, the image data of the detecting elements Gs1-Gsn, Gt1-Gtn may also be discarded.

Further, in the present example, for the image data of s line-th detecting elements Gs1-Gsn for X-ray amount measurement, when in the signal processing section 2, the interpolation processing based on the image data of adjoining s−1, s+1 line-th respective detecting elements G(s−1)1-G(s−1)n, G(s+1)1-G(s+1)n is conducted, it is generated, and for t line-th detecting elements Gt1-Gtn for the X-ray amount measurement, in the signal processing section 2, when the interpolation processing based on the image data of adjoining t−1, t+1 line-th respective detecting elements G(t−1)1-G(t−1)n, G(t+1)1-G(t+1)n is conducted, it may also be generated.

Further, in the radiation image pickup apparatus of the second and the third embodiments, as same as the first embodiment, when FPD conducts the photographing operation, the position of the detecting elements for measuring the X-ray amount may also be fixed, it may also be switched to another line every photographing. When switched to another line every photographing, corresponding to the subject, the optimum line is set, and it is specified that the X-ray amount is measured by the detecting element of the set line.

Further, in the case where s line-th detecting elements Gs1-Gsn for measuring the X-ray amount is switched, faint X-ray or visible light is irradiated under the condition that the subject is fixed before FPD1, when the position and the size of the subject to the photographing area in FPD1 is confirmed, s line-th detecting elements Gs1-Gsn for measuring the X-ray amount may also be set.

Further, in the radiation image pickup apparatus of the first—the third embodiments, the reset of each detecting element is conducted only once simultaneously with all detecting elements, however, a plurality of times reset may also be conducted every line. That is, while the signal ΦRST is made high, the signal ΦV1-ΦVn may also be made high in order.

The radiation image pickup apparatus of the present invention can be adequately used for the image analyzing apparatus such as the medical diagnostic machine by which the subject is photographed by the radiation, and by using the obtained image, analysis is conducted, and the non-destructive inspection machine.

What is claimed is:

1. A radiation image pickup apparatus; comprising:
a plurality of detecting elements arranged in a matrix arrangement in which each of the plurality of detecting elements has a converting element to convert radiation incident from a radiation source into an electric charge corresponding to the amount of the radiation and a switch connected to the converting element;
a plurality of charge transfer lines, each of the plurality of charge transfer lines provided in correspondence to one column of the matrix arrangement and connected to switches of detecting elements on the one column;
an output circuit to retain electric charges from the plurality of charge transfer lines and to output electric signals corresponding to the electric charges; and
a control section to select a first detecting element to measure an amount of radiation during a irradiation period from the plurality of detecting elements;
wherein during the irradiation period, the control section controls all the converting elements of the plurality of detecting elements including the first detecting element converts radiation into electric charges respectively, and the control section makes the switch of the first detecting element “ON” so as to transfer the electric charge trough a corresponding charge transfer line to the output circuit so that the output circuit accumulates electric charge coveted by the converting element of the first detecting element and the control section reads periodically an electric signal corresponding to the electric charge accumulated in accordance with the irradiation period.

2. The radiation image pickup apparatus of claim 1, wherein the control section selects plural detecting elements as the first detecting element.

3. The radiation image pickup apparatus of claim 2, wherein the control section calculates an addition average value from electric signals from the plural first detecting elements and conducts a measurement for an amount of a radiation based on the addition average value.

4. The radiation image pickup apparatus of claim 2, wherein the control section obtains the maximum value of electric signals from the plural first detecting elements and conducts a measurement for an amount of a radiation based on the maximum value.

5. The radiation image pickup apparatus of claim 1, wherein all the plurality of detecting elements including the first detecting element output electric signals as image data based on the amount of radiation incident thereon respectively.

6. The radiation image pickup apparatus of claim 1, wherein the output circuit includes a charge retaining section connected to one of the plurality of charge transfer lines so as to retain an electric charge from the detecting elements and a reset section to reset the charge retaining section, and wherein before irradiation of radiation, the control section controls the reset section to reset the charge retaining section and control the switches to be “ON” so as to reset the converting elements.

7. The radiation image pickup apparatus of claim 1, wherein the plural first detecting elements are plural detecting elements located at plural rows in the matrix arrangement.

8. The radiation image pickup apparatus of claim 7, wherein the output circuit includes plural output circuits provided for each row in the matrix arrangement.

9. The radiation image pickup apparatus of claim 1, wherein the control section selects a first detecting element for each time of radiography to irradiate radiation.

10. The radiation image pickup apparatus of claim 9, wherein the controls section controls the radiation source to emit a faint radiation or visible light before a radiography to irradiate radiation for an object and confirm a radiographing area for the object, and then the control section selects a first detecting element based on the radiographing area.

11. The radiation image pickup apparatus of claim 1, wherein the controls section controls the radiation source to emit a faint radiation or visible light before a radiography to irradiate radiation for an object and confirm a radiographing area for the object, and then the control section set an irradiation area of radiation based on the radiographing area.

12. The radiation image pickup apparatus of claim 1, wherein the output circuit includes an operation amplifier which has a reversal input terminal connected to the charge transfer line and a non-reversal input terminal provided with a reference voltage and a capacitance element connected between the reversal input terminal of the operation amplifier and an output terminal.

13. The radiation image pickup apparatus of claim 1, wherein the output circuit includes a charge-voltage converting section to convert a charge amount to a voltage.

14. The radiation image pickup apparatus of claim 1, wherein the control section outputs a stop signal to stop the radiation source to irradiate radiation based on the value of the electric signal.

15. A radiation image pickup method with a radiation image pickup apparatus equipped with a plurality of detecting elements arranged in a matrix arrangement in which each of the plurality of detecting elements has a converting element to convert radiation incident thereon into an electric charge corresponding to the amount of the radiation and a switch connected to the converting element; a plurality of charge transfer lines, each of the plurality of charge transfer lines provided in correspondence to one column of the matrix arrangement and connected to switches of detecting elements on the one column; an output circuit to retain electric charges from the plurality of charge transfer lines and to output electric signals corresponding to the electric charges; and a control section to control the plurality of detecting elements, the plurality of charge transfer lines and the output circuit; the radiation image pickup method comprising the steps of:
selecting a first detecting element to measure an amount of radiation during a irradiation period from the plurality of detecting elements;
controlling all the converting elements of the plurality of detecting elements including the first detecting element to convert radiation into electric charges respectively and the switch of the first detecting element to become “ON” so as to transfer the electric charge trough a corresponding charge transfer line to the output circuit during the irradiation period so that the output circuit accumulates electric charge coveted by the converting element of the first detecting element; and
reading periodically an electric signal corresponding to the electric charge accumulated in accordance with the irradiation period.

16. The radiation image pickup method of claim 15, wherein the selecting step selects plural detecting elements as the first detecting element.

17. The radiation image pickup method of claim 16, further comprising a calculating step of calculating an addition average value from electric signals from the plural first detecting elements and a measurement for an amount of a radiation is conducted based on the addition average value.

18. The radiation image pickup method of claim 16, further comprising an obtaining step of obtaining the maximum value of electric signals from the plural first detecting elements and a measurement for an amount of a radiation is conducted based on the maximum value.

19. The radiation image pickup method of claim 15, wherein all the plurality of detecting elements including the first detecting element output electric signals as image data based on the amount of radiation incident thereon respectively.

20. The radiation image pickup method of claim 15, wherein the selecting selects a first detecting element for each time of radiography to irradiate radiation.

21. The radiation image pickup method of claim 15, further comprising a step of stopping the radiation source to irradiate radiation based on the value of the electric signal.
